(19) United States
(12) Patent Application Publication
(10) Pub. No.: US 2026/0260626 A1
(43) Pub. Date: Sep. 3, 2026

(54) DISPLAY DEVICE

(71) Applicant: LG DISPLAY CO., LTD., Seoul (KR)

(72) Inventor: Yeonji Ryu, Paju-si (KR)

(21) Appl. No.: 19/430,078

(22) Filed: Dec. 22, 2025

(30) Foreign Application Priority Data
Feb. 28, 2025 (KR) 10-2025-0026297

(51) Int. Cl. G09G 3/3291

(52) U.S. Cl. CPC G09G 3/3291; G09G 2300/0852; G09G 2310/0289; G09G 2320/0233; G09G 2320/0276; G09G 2330/023; G09G 2330/028; G09G 2354/00; G09G 2360/14

(57) ABSTRACT

A display device having improved luminance uniformity through a first controller, a second controller, a first gamma circuit that generates a general gamma voltage, and a second gamma circuit that generates an optical gamma voltage.

### CROSS REFERENCE TO RELATED APPLICATION

This application claims priority from and the benefit of Korean Patent Application No. 10-2025-0026297, filed on February 28, 2025, which is hereby incorporated by reference for all purposes as if fully set forth herein.

### BACKGROUND

### Field

Embodiments of the invention relate generally to a device and, more particularly, to a display device having improved luminance uniformity.

### Discussion of the Background

As the information-oriented society has developed, demand for display devices for displaying images has increased in various forms, and recently, various display devices, such as liquid crystal display devices and organic light-emitting display devices, have been utilized.

A plurality of sub-pixels may be disposed in a display panel. In order to cause each of the plurality of sub-pixels to emit light with a uniform luminance, compensation for luminance may be performed.

The above information disclosed in this Background section is only for understanding of the background of the inventive concepts, and, therefore, it may contain information that does not constitute prior art.

### SUMMARY

Display devices according to embodiments of the invention are capable of improving luminance uniformity through a plurality of gamma circuits. The improved luminance uniformity may be in both a general area and an optical area through the plurality of gamma circuits. In addition, low power consumption may be achieved by uniformly compensating luminance.

Additional features of the inventive concepts will be set forth in the description which follows, and in part will be apparent from the description, or may be learned by practice of the inventive concepts.

According to one or more embodiments of the invention a display device includes: a display panel including a general area and an optical area different from the general area; a source drive circuit that supplies a voltage for displaying an image to the display panel; a first gamma circuit that supplies a general gamma voltage to the source drive circuit; a second gamma circuit that supplies an optical gamma voltage different from the general gamma voltage to the source drive circuit; a first controller that controls the first gamma circuit and supplies general image data to the first gamma circuit; and a second controller that controls the second gamma circuit, supplies optical image data to the second gamma circuit, and controls a target different from a target controlled by the first controller.

The source drive circuit may generate a general data voltage based on the general gamma voltage, and may generate an optical data voltage based on the optical gamma voltage.

The source drive circuit may supply the general data voltage to the sub-pixels disposed in the general area, and may supply the optical data voltage to the sub-pixels disposed in the optical area.

The arrangement density of the sub-pixels disposed in the optical area may be lower than the arrangement density of the sub-pixels disposed in the general area.

The optical area may be an area in which sub-pixels for displaying an image are disposed, and the optical area may overlap an optical device.

The optical device may be a camera sensor or an optical sensor.

The display device may further include a first storage circuit that is electrically connected to the first gamma circuit and the first controller and stores general image compensation data, and a second storage circuit that is electrically connected to the second gamma circuit and the second controller and stores optical image compensation data different from the general image compensation data.

The first gamma circuit may generate a general gamma voltage based on the general image data transmitted from the first controller and the general image compensation data supplied from the first storage circuit, and the second gamma circuit may generate an optical gamma voltage based on the optical image data transmitted from the second controller and the optical image compensation data supplied from the second storage circuit.

The first controller may receive the general image compensation data from the first storage circuit, generate general final image data based on the general image data and the general image compensation data, and supply the general final image data to the first gamma circuit, and the second controller may receive the optical image compensation data from the second storage circuit, generate optical final image data based on the optical image data and the optical image compensation data, and supply the optical final image data to the second gamma circuit.

The first gamma circuit may transmit signals to the first controller and the first storage circuit by a serial communication protocol, and the second gamma circuit may transmit signals to the second controller and the second storage circuit by the serial communication protocol.

The number of targets controlled by the first controller may be greater than the number of targets controlled by the second controller.

The first controller may receive a first feedback signal from the display panel, and the first controller may receive a second feedback signal from the source drive circuit.

A period in which the second feedback signal is supplied to the first controller may be shorter than a period in which the first feedback signal is supplied to the first controller.

The display device may further include a first power circuit that generates a source voltage, a gate high voltage, and a gate low voltage, a second power circuit that generates a driving voltage and a base voltage, and a level shifter that receives the gate high voltage and the gate low voltage from the first power circuit.

The first power circuit may supply the source voltage to the first gamma circuit and the second gamma circuit, the first gamma circuit may generate the general gamma voltage based on the source voltage, and the second gamma circuit may generate the optical gamma voltage based on the source voltage.

The first controller may communicate signals with the first power circuit and the second power circuit by a serial communication protocol.

The first controller may be electrically connected to the level shifter and may control the level shifter.

The display device may further include a flash memory that transmits and receives signals to and from the first controller through serial communication.

The display device may further include a touch circuit that supplies a touch driving signal to the display panel, receives a touch sensing signal from the display panel, and communicates signals with an external device by a serial communication protocol and an interrupt request communication protocol.

The display device may further include a control printed circuit board on which the first controller and the second controller are disposed, and a source printed circuit board on which the first gamma circuit and the second gamma circuit are disposed.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 illustrate front and side views of a display device according to embodiments of the invention.

FIG. 2 is a system configuration diagram of a display device according to embodiments of the invention.

FIG. 3 is an equivalent circuit diagram of sub-pixels in a display panel according to embodiments of the invention.

FIG. 4 is a diagram illustrating an arrangement of sub-pixels in three areas included in a display area of a display panel according to embodiments of the invention.

FIG. 5 is a diagram illustrating an arrangement of signal lines in each of a first optical area and a general area in a display panel according to embodiments of the invention.

FIG. 6 is a diagram illustrating an arrangement of signal lines in each of a second optical area and a general area in a display panel according to embodiments of the invention.

FIG. 7 illustrates cross-sectional views of a display panel according to embodiments of the invention.

FIG. 8 is a diagram illustrating a display device according to embodiments of the invention.

FIG. 9 is a diagram illustrating signal transmission paths of a display device according to embodiments of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

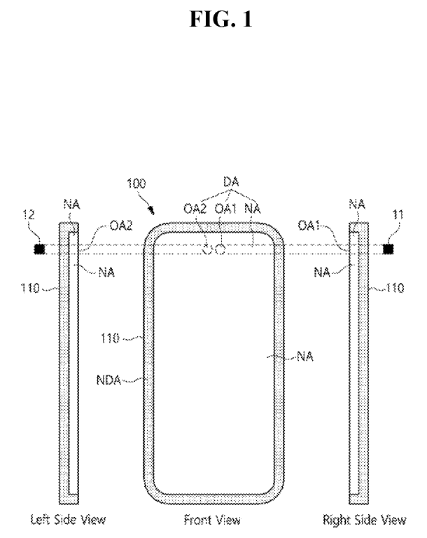

FIG. 1 illustrates front and side views of a display device 100 according to embodiments of the invention.

Referring to FIG. 1, the display device 100 according to embodiments of the invention may include a display panel 110 that displays an image and one or more optical electronic devices 11 and 12.

The display panel 110 may include a display area DA in which an image is displayed and a non-display area NDA in which an image is not displayed.

A plurality of sub-pixels may be disposed in the display area DA, and various signal lines for driving the plurality of sub-pixels may be disposed therein.

The non-display area NDA may be an outer area of the display area DA. Various signal lines may be disposed in the non-display area NDA, and various driving circuits may be connected thereto.

Referring to FIG. 1, one or more optical areas OA1 and OA2 may be areas that overlap one or more optical electronic devices 11 and 12.

In the example of FIG. 1, the display area DA may include a general area NA, a first optical area OA1, and a second optical area OA2. In the example of FIG. 1, the general area NA is present between the first optical area OA1 and the second optical area OA2. At least a portion of the first optical area OA1 may overlap the first optical electronic device 11, and at least a portion of the second optical area OA2 may overlap the second optical electronic device 12.

The one or more optical areas OA1 and OA2 may have both an image display structure and a light transmission structure. That is, because the one or more optical areas OA1 and OA2 are part of the display area DA, sub-pixels for image display may be disposed in the one or more optical areas OA1 and OA2. In addition, the one or more optical areas OA1 and OA2 may have a light transmission structure for transmitting light to the one or more optical electronic devices 11 and 12.

The first optical electronic device 11 may be a camera, and the second optical electronic device 12 may be a detection sensor, such as a proximity sensor or a luminance sensor. For example, the detection sensor may be an infrared sensor that detects infrared light.

Although the general area NA and the one or more optical areas OA1 and OA2 included in the display area DA are all areas in which image display is possible, the general area NA is an area in which a light transmission structure is not required, and the one or more optical areas OA1 and OA2 are areas in which a light transmission structure is required.

Accordingly, the one or more optical areas OA1 and OA2 may have a transmittance above a certain level, and the general area NA may have no light transmissivity or at least a low transmittance below a certain level.

In the display device 100 according to embodiments of the invention, when the first optical electronic device 11, which is not exposed to the outside and is hidden under the display panel 110, is a camera, the display device 100 according to embodiments of the invention may be referred to as a display to which an under-display camera (UDC) technology is applied.

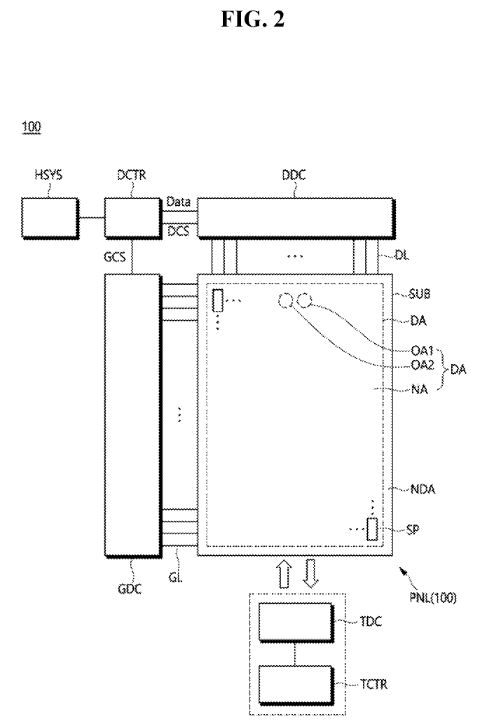

FIG. 2 is a system configuration diagram of a display device 100 according to embodiments of the invention.

Referring to FIG. 2, the display device 100 may include, as components for image display, a display panel PNL and a display driving circuit. The display panel PNL corresponds to the display panel 110 of FIG. 1.

The display driving circuit is a circuit for driving the display panel PNL and may include a data driving circuit DDC, a gate driving circuit GDC, and a display controller DCTR.

The display panel PNL may include a substrate SUB and a plurality of sub-pixels SP disposed on the substrate SUB. In addition, the display panel PNL may further include various types of signal lines for driving the plurality of sub-pixels SP.

The display device 100 according to embodiments of the invention may be a liquid crystal display device or may be a self-emissive display device in which the display panel PNL emits light by itself. When the display device 100 according to embodiments of the invention is a self-emissive display device, each of the plurality of sub-pixels SP may include a light-emitting device.

The structure of each of the plurality of sub-pixels SP may vary depending on the type of the display device 100. For example, when the display device 100 is a self-emissive display device in which the sub-pixels SP emit light by themselves, each sub-pixel SP may include a light-emitting device, one or more transistors, and one or more capacitors.

For example, the various types of signal lines may include a plurality of data lines DL that deliver data signals (also referred to as data voltages or image signals) and a plurality of gate lines GL that deliver gate signals (also referred to as scan signals).

The plurality of data lines DL and the plurality of gate lines GL may intersect each other. Each of the plurality of data lines DL may be disposed to extend in a first direction. Each of the plurality of gate lines GL may be disposed to extend in a second direction.

The first direction may be a column direction and the second direction may be a row direction, or the first direction may be a row direction and the second direction may be a column direction.

The data driving circuit DDC is a circuit for driving the plurality of data lines DL and may output data signals to the plurality of data lines DL. The gate driving circuit GDC is a circuit for driving the plurality of gate lines GL and may output gate signals to the plurality of gate lines GL.

The display controller DCTR is a device for controlling the data driving circuit DDC and the gate driving circuit GDC, and may control the driving timing for the plurality of data lines DL and the driving timing for the plurality of gate lines GL.

The display controller DCTR may supply a data driving control signal DCS to the data driving circuit DDC to control the data driving circuit DDC, and may supply a gate driving control signal GCS to the gate driving circuit GDC to control the gate driving circuit GDC.

The display controller DCTR may receive input image data from a host system HSYS and may supply image data Data to the data driving circuit DDC based on the input image data.

The data driving circuit DDC may supply data signals to the plurality of data lines DL under the driving timing control of the display controller DCTR.

The data driving circuit DDC may receive image data Data in a digital form from the display controller DCTR, convert the received image data Data into data signals in an analog form, and output the data signals to the plurality of data lines DL.

The gate driving circuit GDC may supply gate signals to the plurality of gate lines GL under the timing control of the display controller DCTR. The gate driving circuit GDC may receive a first gate voltage corresponding to a turn-on level voltage and a second gate voltage corresponding to a turn-off level voltage together with various gate driving control signals GCS, generate gate signals, and supply the generated gate signals to the plurality of gate lines GL.

The display device 100 according to embodiments of the invention may further include a touch sensor and a touch sensing circuit for sensing the touch sensor to detect whether a touch has occurred by a touch object such as a finger or a pen, or to detect a touch position, in order to provide a touch sensing function in addition to the image display function.

The touch sensing circuit may include a touch driving circuit TDC that drives and senses the touch sensor to generate and output touch sensing data, and a touch controller TCTR that may detect a touch occurrence or detect a touch position using the touch sensing data.

The touch sensor may include a plurality of touch electrodes. The touch sensor may further include a plurality of touch lines for electrically connecting the plurality of touch electrodes to the touch driving circuit TDC.

The touch driving circuit TDC may supply a touch driving signal to at least one of the plurality of touch electrodes and may sense at least one of the plurality of touch electrodes to generate touch sensing data.

The touch sensing circuit may perform touch sensing in a self-capacitance sensing method or a mutual-capacitance sensing method.

In the display panel PNL, the display area DA may include the general area NA and one or more optical areas OA1 and OA2. However, for convenience of explanation, it is assumed that the display area DA includes both the first optical area OA1 and the second optical area OA2 (FIG. 1).

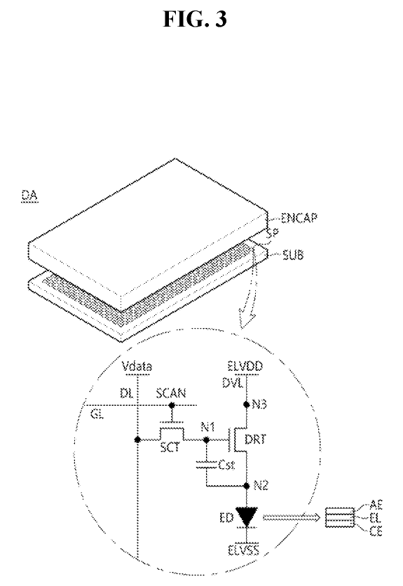

FIG. 3 is an equivalent circuit diagram of a sub-pixel SP in the display panel PNL according to embodiments of the invention.

Each of the sub-pixels SP disposed in the general area NA, the first optical area OA1, and the second optical area OA2 included in the display area DA of the display panel PNL may include a light-emitting device ED, a driving transistor DRT for driving the light-emitting device ED, a scan transistor SCT for delivering a data voltage Vdata to a first node N1 of the driving transistor DRT, and a storage capacitor Cst for maintaining a constant voltage during one frame.

The driving transistor DRT may include a first node N1 to which the data voltage may be applied, a second node N2 electrically connected to the light-emitting device ED, and a third node N3 to which a driving voltage ELVDD is applied from a driving voltage line DVL. In the driving transistor DRT, the first node N1 may be a gate node, the second node N2 may be a source node or a drain node, and the third node N3 may be a drain node or a source node.

The light-emitting device ED may include an anode electrode AE, an emission layer EL, and a cathode electrode CE. The anode electrode AE may be a pixel electrode disposed in each sub-pixel SP and may be electrically connected to the second node N2 of the driving transistor DRT of each sub-pixel SP. The cathode electrode CE may be a common electrode commonly disposed in the plurality of sub-pixels SP and may be supplied with a base voltage ELVSS.

For example, the anode electrode AE may be a pixel electrode and the cathode electrode CE may be a common electrode. Conversely, the anode electrode AE may be a common electrode and the cathode electrode CE may be a pixel electrode. Hereinafter, for convenience of explanation, it is assumed that the anode electrode AE is the pixel electrode and the cathode electrode CE is the common electrode.

The scan transistor SCT may be turned on and off by a scan signal SCAN, which is a gate signal applied through a gate line GL, and may be electrically connected between the first node N1 of the driving transistor DRT and a data line DL.

The storage capacitor Cst may be electrically connected between the first node N1 and the second node N2 of the driving transistor DRT.

As illustrated in FIG. 3, each sub-pixel SP may have a 2T (Transistor) 1C (Capacitor) structure including two transistors (DRT, SCT) and one capacitor (Cst), and in some cases, may further include one or more additional transistors or one or more additional capacitors.

Each of the driving transistor DRT and the scan transistor SCT may be an n-type transistor or a p-type transistor.

Because the circuit elements in each sub-pixel SP (particularly, the light-emitting device ED) are vulnerable to external moisture or oxygen, an encapsulation layer ENCAP for preventing or reducing external moisture or oxygen from penetrating into the circuit elements (particularly, the light-emitting device ED) may be disposed in the display panel PNL. The encapsulation layer ENCAP may be disposed to cover the light-emitting devices ED.

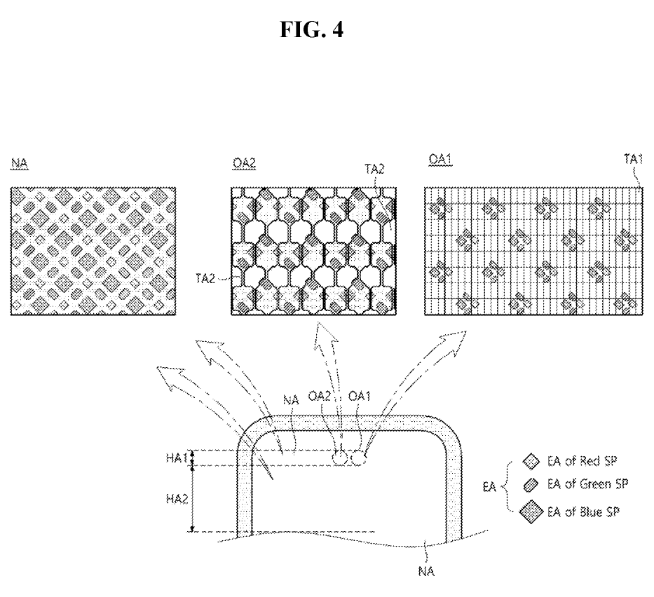

FIG. 4 is a diagram illustrating arrangements of sub-pixels SP in three areas (NA, OA1, OA2) included in the display area DA of the display panel PNL according to embodiments of the invention.

Referring to FIG. 4, a plurality of sub-pixels SP may be disposed in each of the general area NA, the first optical area OA1, and the second optical area OA2 included in the display area DA.

Each of the general area NA, the first optical area OA1, and the second optical area OA2 may include emission areas EA of red sub-pixels (Red SP), emission areas EA of green sub-pixels (Green SP), and emission areas EA of blue sub-pixels (Blue SP).

Referring to FIG. 4, the general area NA may include emission areas EA without including a light transmission structure.

However, the first optical area OA1 and the second optical area OA2 may include not only the emission areas EA but also a light transmission structure.

Accordingly, the first optical area OA1 may include the emission areas EA and first transmission areas TA1, and the second optical area OA2 may include the emission areas EA and second transmission areas TA2.

The emission areas EA and the transmission areas TA1 and TA2 may be distinguished according to whether light transmission is possible. That is, the emission areas EA may be areas in which light transmission is impossible, and the transmission areas TA1 and TA2 may be areas in which light transmission is possible.

In addition, the emission areas EA and the transmission areas TA1 and TA2 may be distinguished according to the presence or absence of formation of a specific metal layer CE. For example, the cathode electrode CE may be formed in the emission areas EA and may not be formed in the transmission areas TA1 and TA2. The emission areas EA may have a light shield layer formed therein, and the transmission areas TA1 and TA2 may have no light shield layer formed therein.

Because the first optical area OA1 includes the first transmission areas TA1 and the second optical area OA2 includes the second transmission areas TA2, both the first optical area OA1 and the second optical area OA2 are areas through which light may be transmitted.

The transmittance (degree of transmission) of the first optical area OA1 and the transmittance (degree of transmission) of the second optical area OA2 may be the same.

Alternatively, the transmittance (degree of transmission) of the first optical area OA1 and the transmittance (degree of transmission) of the second optical area OA2 may be different from each other.

In addition, as illustrated in FIG. 4, in embodiments of the invention, the transmission areas TA1 and TA2 may also be referred to as “transparent areas”, and the transmittance may also be referred to as “transparency”.

In addition, as illustrated in FIG. 4, in embodiments of the invention, it is assumed that the first optical area OA1 and the second optical area OA2 are located at an upper end of the display area DA of the display panel PNL and are arranged side by side.

Referring to FIG. 4, the display area in which the first optical area OA1 and the second optical area OA2 are disposed is referred to as a first display area HA1, and the display area in which the first optical area OA1 and the second optical area OA2 are not disposed is referred to as a second display area HA2.

Referring to FIG. 4, the first display area HA1 may include the general area NA, the first optical area OA1, and the second optical area OA2. The second display area HA2 may include only the general area NA.

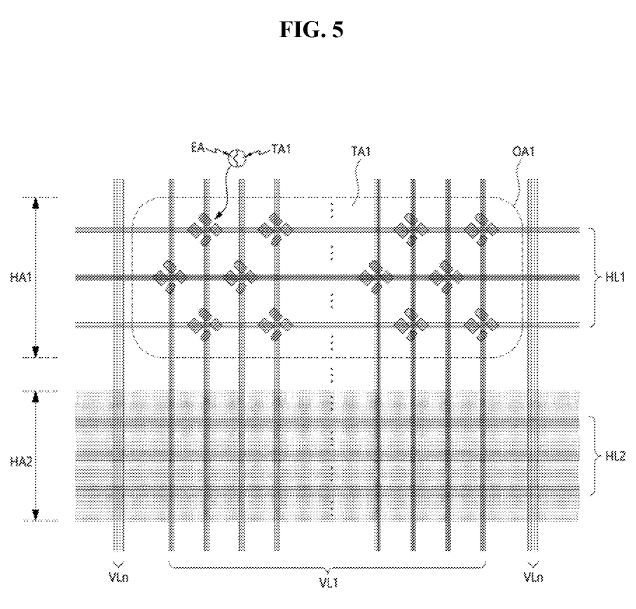

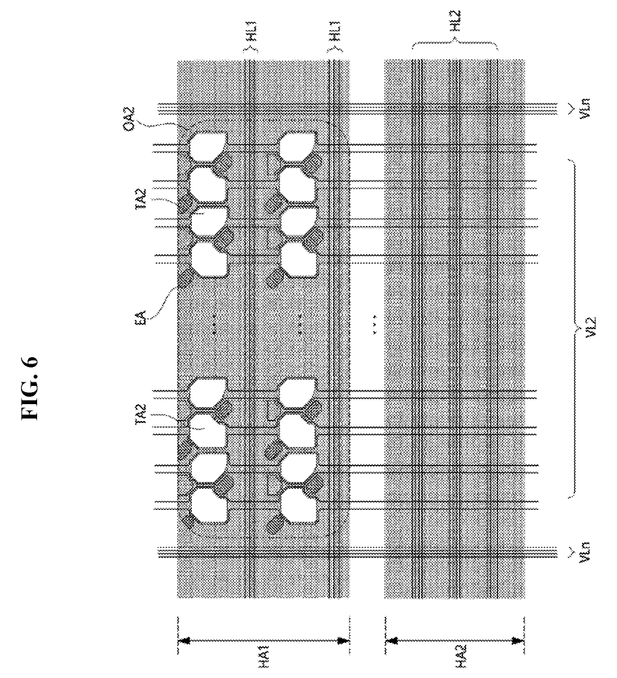

FIG. 5 is a diagram illustrating arrangements of signal lines in each of the first optical area OA1 and the general area NA in the display panel PNL according to embodiments of the invention, and FIG. 6 is a diagram illustrating arrangements of signal lines in each of the second optical area OA2 and the general area NA in the display panel PNL according to embodiments of the invention.

The first display area HA1 illustrated in FIG. 5 and FIG. 6 is a part of the first display area HA1 in the display panel PNL, and the second display area HA2 is a part of the second display area HA2 in the display panel PNL.

The first optical area OA1 illustrated in FIG. 5 is a part of the first optical area OA1 in the display panel PNL, and the second optical area OA2 illustrated in FIG. 6 is a part of the second optical area OA2 in the display panel PNL.

Referring to FIG. 5 and FIG. 6, the first display area HA1 may include the general area NA, the first optical area OA1, and the second optical area OA2. The second display area HA2 may include the general area NA.

In the display panel 110, various types of horizontal lines HL1 and HL2 may be disposed, and various types of vertical lines VLn, VL1, and VL2 may be disposed.

In embodiments of the invention, the horizontal direction and the vertical direction refer to two intersecting directions, and the horizontal direction and the vertical direction may vary depending on the viewing orientation. For example, in embodiments of the invention, the horizontal direction may refer to a direction in which one gate line GL extends and is disposed, and the vertical direction may refer to a direction in which one data line DL extends and is disposed. This horizontal/vertical distinction is given by way of example.

Referring to FIG. 5 and FIG. 6, the horizontal lines disposed in the display panel PNL may include first horizontal lines HL1 disposed in the first display area HA1 and second horizontal lines HL2 disposed in the second display area HA2.

The horizontal lines disposed in the display panel PNL may be gate lines GL. That is, the first horizontal lines HL1 and the second horizontal lines HL2 may be gate lines GL. The gate lines GL may include various types of gate lines depending on the structure of the sub-pixel SP.

Referring to FIG. 5 and FIG. 6, the vertical lines disposed in the display panel PNL may include general vertical lines VLn disposed only in the general area NA, first vertical lines VL1 passing through both the first optical area OA1 and the general area NA, and second vertical lines VL2 passing through both the second optical area OA2 and the general area NA.

The vertical lines disposed in the display panel PNL may include data lines DL, driving voltage lines DVL, and may further include reference voltage lines, initialization voltage lines, and the like. That is, the general vertical lines VLn, the first vertical lines VL1, and the second vertical lines VL2 may include data lines DL, driving voltage lines DVL, and may further include reference voltage lines, initialization voltage lines, and the like.

Referring to FIG. 5, the first optical area OA1 included in the first display area HA1 may include emission areas EA and first transmission areas TA1. In the first optical area OA1, an outer region of each first transmission area TA1 may include emission areas EA.

Referring to FIG. 5, to improve the transmittance of the first optical area OA1, the first horizontal lines HL1 passing through the first optical area OA1 may pass while avoiding the first transmission areas TA1 in the first optical area OA1.

Accordingly, each of the first horizontal lines HL1 passing through the first optical area OA1 may include a curved section or a bending section that bypasses outside the outer edge of each first transmission area TA1.

Accordingly, the first horizontal lines HL1 disposed in the first display area HA1 and the second horizontal lines HL2 disposed in the second display area HA2 may differ from each other in shape or length. That is, the first horizontal lines HL1 passing through the first optical area OA1 and the second horizontal lines HL2 not passing through the first optical area OA1 may differ from each other in shape or length.

In addition, to improve the transmittance of the first optical area OA1, the first vertical lines VL1 passing through the first optical area OA1 may pass while avoiding the first transmission areas TA1 in the first optical area OA1.

Accordingly, each of the first vertical lines VL1 passing through the first optical area OA1 may include a curved section or a bending section that bypasses outside the outer edge of each first transmission area TA1.

Accordingly, the first vertical lines VL1 passing through the first optical area OA1 and the general vertical lines VLn disposed in the general area NA without passing through the first optical area OA1 may differ from each other in shape or length.

Referring to FIG. 5, the first transmission areas TA1 included in the first optical area OA1 in the first display area HA1 may be arranged in an oblique direction.

Referring to FIG. 5, in the first optical area OA1 in the first display area HA1, emission areas EA may be disposed between two first transmission areas TA1 adjacent in the left-right direction. In the first optical area OA1 in the first display area HA1, emission areas EA may be disposed between two first transmission areas TA1 adjacent in the up-down direction.

Referring to FIG. 5, each of the first horizontal lines HL1 disposed in the first display area HA1, that is, each of the first horizontal lines HL1 passing through the first optical area OA1, may include at least one curved section or bending section that bypasses outside the outer edge of each first transmission area TA1.

Referring to FIG. 6, the second optical area OA2 included in the first display area HA1 may include emission areas EA and second transmission areas TA2. In the second optical area OA2, an outer region of each second transmission area TA2 may include emission areas EA.

The positions and arrangement states of the emission areas EA and the second transmission areas TA2 in the second optical area OA2 may be the same as the positions and arrangement states of the emission areas EA and the second transmission areas TA2 in the first optical area OA1 of FIG. 5.

Alternatively, as illustrated in FIG. 6, the positions and arrangement states of the emission areas EA and the second transmission areas TA2 in the second optical area OA2 may be different from the positions and arrangement states of the emission areas EA and the second transmission areas TA2 in the first optical area OA1 of FIG. 5.

For example, referring to FIG. 6, in the second optical area OA2, the second transmission areas TA2 may be arranged in a horizontal direction (left-right direction). No emission area EA may be disposed between two second transmission areas TA2 adjacent in the horizontal direction (left-right direction). In addition, the emission areas EA in the second optical area OA2 may be disposed between second transmission areas TA2 adjacent in the vertical direction (up-down direction). That is, the emission areas EA may be disposed between two rows of the second transmission areas TA2.

The first horizontal lines HL1 may pass through the second optical area OA2 and the surrounding general area NA in the first display area HA1 in the same manner as in FIG. 5.

Alternatively, as illustrated in FIG. 6, the first horizontal lines HL1 may pass through the second optical area OA2 and the surrounding general area NA in the first display area HA1 in a manner different from that in FIG. 5.

This is because the positions and arrangement states of the emission areas EA and the second transmission areas TA2 in the second optical area OA2 of FIG. 6 are different from the positions and arrangement states of the emission areas EA and the second transmission areas TA2 in the first optical area OA1 of FIG. 5.

Referring to FIG. 6, the first horizontal lines HL1 may pass in a straight line between the second transmission areas TA2 adjacent in the vertical direction (up-down direction) in the second optical area OA2 in the first display area HA1 without a curved section or a bending section.

In other words, one first horizontal line HL1 may have a curved section or a bending section in the first optical area OA1 but may have no curved section or bending section in the second optical area OA2.

To improve the transmittance of the second optical area OA2, the second vertical lines VL2 passing through the second optical area OA2 may pass while avoiding the second transmission areas TA2 in the second optical area OA2.

Accordingly, each of the second vertical lines VL2 passing through the second optical area OA2 may include a curved section or a bending section that bypasses outside the outer edge of each second transmission area TA2.

Accordingly, the second vertical lines VL2 passing through the second optical area OA2 and the general vertical lines VLn disposed in the general area NA without passing through the second optical area OA2 may differ from each other in shape or length.

As illustrated in FIG. 5, the first horizontal lines HL1 passing through the first optical area OA1 may have curved sections or bending sections that bypass outside the outer edges of the first transmission areas TA1.

Referring to FIG. 5 and FIG. 6, according to the light transmission structure, because the first optical area OA1 at least partially overlapping the first optical electronic device 11 includes a plurality of first transmission areas TA1, and the second optical area OA2 at least partially overlapping the second optical electronic device 12 includes a plurality of second transmission areas TA2, the first optical area OA1 and the second optical area OA2 may have a smaller number of sub-pixels per unit area than the general area NA.

The number of sub-pixels SP electrically connected to the first horizontal lines HL1 passing through the first optical area OA1 and the second optical area OA2 and the number of sub-pixels SP electrically connected to the second horizontal lines HL2 disposed only in the general area NA without passing through the first optical area OA1 and the second optical area OA2 may differ from each other.

The number (first number) of sub-pixels SP electrically connected to the first horizontal lines HL1 passing through the first optical area OA1 and the second optical area OA2 may be less than the number (second number) of sub-pixels SP electrically connected to the second horizontal lines HL2 disposed only in the general area NA without passing through the first optical area OA1 and the second optical area OA2.

The difference between the first number and the second number may vary according to the resolution of each of the first optical area OA1 and the second optical area OA2 and the resolution of the general area NA. For example, as the difference in resolution between each of the first optical area OA1 and the second optical area OA2 and the resolution of the general area NA increases, the difference between the first number and the second number may increase.

As described above, because the number (first number) of sub-pixels SP electrically connected to the first horizontal lines HL1 passing through the first optical area OA1 and the second optical area OA2 is less than the number (second number) of sub-pixels SP electrically connected to the second horizontal lines HL2 disposed only in the general area NA without passing through the first optical area OA1 and the second optical area OA2, an area in which the first horizontal lines HL1 overlap with other surrounding electrodes or lines may be smaller than an area in which the second horizontal lines HL2 overlap with other surrounding electrodes or lines.

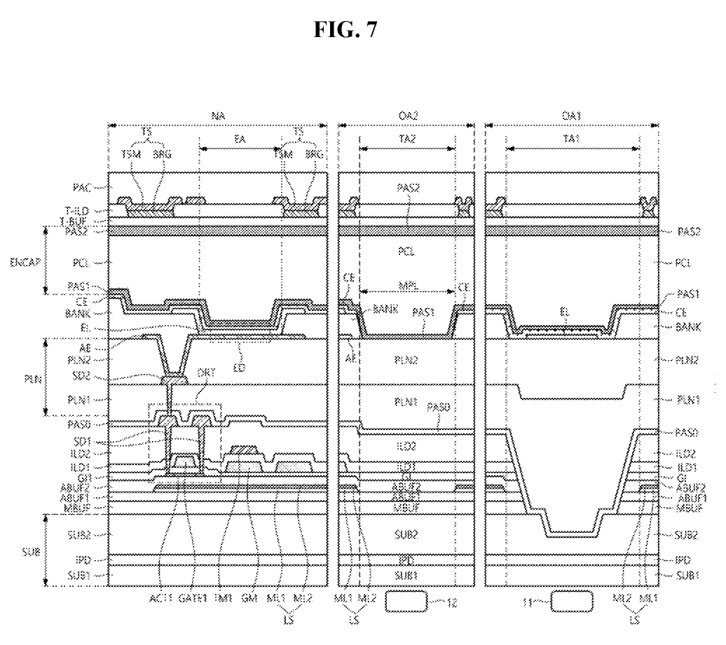

FIG. 7 illustrates cross-sectional views of each of the general area NA, the first optical area OA1, and the second optical area OA2 included in the display area DA of the display panel PNL according to embodiments of the invention.

First, with reference to FIG. 7, the stacked structure of the general area NA will be described. The emission area EA included in each of the first optical area OA1 and the second optical area OA2 may have the same stacked structure as the emission area EA in the general area NA.

Referring to FIG. 7, the substrate SUB may include a first substrate SUB1, an interlayer insulating film IPD, and a second substrate SUB2. The interlayer insulating film IPD may be located between the first substrate SUB1 and the second substrate SUB2. By configuring the substrate SUB to include the first substrate SUB1, the interlayer insulating film IPD, and the second substrate SUB2, moisture penetration may be prevented or reduced. For example, the first substrate SUB1 and the second substrate SUB2 may be polyimide (PI) substrates. The first substrate SUB1 may be referred to as a “primary PI substrate”, and the second substrate SUB2 may be referred to as a “secondary PI substrate”.

Referring to FIG. 7, various patterns ACT1, SD1, and GME1 for forming transistors such as the driving transistor DRT, various insulating films MBUF, ABUF1, ABUF2, GI, ILD1, ILD2, and PAS0, and various metal patterns TM1, GM, ML1, and ML2 may be disposed on the substrate SUB.

Referring to FIG. 7, a multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. The first metal layer ML1 and the second metal layer ML2 may be light shield layers LS for shielding light.

A second active buffer layer ABUF2 may be disposed on the first metal layer ML1 and the second metal layer ML2. A first active layer ACT1 of the driving transistor DRT may be disposed on the second active buffer layer ABUF2.

A first gate insulating film GI1 may be disposed to cover the first active layer ACT1.

A first gate electrode GME1 of the driving transistor DRT may be disposed on the first gate insulating film GI1. At a location different from the formation position of the driving transistor DRT, a gate material layer GM may be disposed on the first gate insulating film GI1 together with the first gate electrode GME1 of the driving transistor DRT.

A first interlayer insulating film ILD1 may be disposed to cover the first gate electrode GME1 and the gate material layer GM. A metal pattern TM1 may be disposed on the first interlayer insulating film ILD1. The metal pattern TM1 may be located at a position different from the formation position of the driving transistor DRT. A second interlayer insulating film ILD2 may be disposed to cover the metal pattern TM1 on the first interlayer insulating film ILD1.

Two first source-drain electrode patterns SD1 may be disposed on the second interlayer insulating film ILD2. Of the two first source-drain electrode patterns SD1, one is a source node of the driving transistor DRT, and the other is a drain node of the driving transistor DRT. The two first source-drain electrode patterns SD1 may be electrically connected to one side and the other side of the first active layer ACT1 through contact holes in the second interlayer insulating film ILD2, the first interlayer insulating film ILD1, and the first gate insulating film GI1.

In the first active layer ACT1, a portion overlapping with the first gate electrode GME1 is a channel region. One of the two first source-drain electrode patterns SD1 may be connected to one side of the channel region in the first active layer ACT1, and the other of the two first source-drain electrode patterns SD1 may be connected to the other side of the channel region in the first active layer ACT1.

A passivation layer PAS0 is disposed to cover the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected, through a contact hole in the first planarization layer PLN1, to one of the two first source-drain electrode patterns SD1 (corresponding to the second node N2 of the driving transistor DRT in the sub-pixel SP of FIG. 3).

The second planarization layer PLN2 may be disposed to cover the second source-drain electrode pattern SD2. A light-emitting device ED may be disposed on the second planarization layer PLN2.

Referring to the stacked structure of the light-emitting device ED, an anode electrode AE may be disposed on the second planarization layer PLN2. The anode electrode AE may be electrically connected to the second source-drain electrode pattern SD2 through a contact hole in the second planarization layer PLN2.

A bank BANK may be disposed to cover a portion of the anode electrode AE. A portion of the bank BANK corresponding to the emission area EA of the sub-pixel SP may be opened.

A portion of the anode electrode AE may be exposed through the opening of the bank BANK. An emission layer EL may be located on a side surface of the bank BANK and in the opening of the bank BANK. The whole or part of the emission layer EL may be located between adjacent banks BANK.

In the opening of the bank BANK, the emission layer EL may be in contact with the anode electrode AE. A cathode electrode CE may be disposed on the emission layer EL.

The light-emitting device ED may be formed by the anode electrode AE, the emission layer EL, and the cathode electrode CE. The emission layer EL may include an organic film.

An encapsulation layer ENCAP may be disposed on the above-described light-emitting device ED.

The encapsulation layer ENCAP may have a single-layer structure or a multi-layer structure. For example, as illustrated in FIG. 7, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest and may serve as a planarization layer.

The first encapsulation layer PAS1 may be disposed on a cathode electrode CE and may be disposed closest to the light-emitting device ED. The first encapsulation layer PAS1 may be formed of an inorganic insulating material capable of low-temperature deposition. For example, the first encapsulation layer PAS1 may be silicon nitride (SiNₓ), silicon oxide (SiOₓ), silicon oxynitride (SiON), or aluminum oxide (Al₂O₃). Because the first encapsulation layer PAS1 is deposited in a low-temperature atmosphere, during the deposition process, the first encapsulation layer PAS1 may reduce or prevent an emission layer EL including an organic material vulnerable to a high-temperature atmosphere from being damaged.

The second encapsulation layer PCL may be formed to have a smaller area than the first encapsulation layer PAS1. In this case, the second encapsulation layer PCL may be formed to expose both ends of the first encapsulation layer PAS1. The second encapsulation layer PCL may serve as a buffer for alleviating stress between layers according to bending of the display device 100 and may also serve to enhance planarization performance. For example, the second encapsulation layer PCL may be acrylic resin, epoxy resin, polyimide, polyethylene, or silicon oxycarbide (SiOC) and may be formed of an organic insulating material. For example, the second encapsulation layer PCL may also be formed by an ink-jet method.

A third encapsulation layer PAS2 may be formed on the substrate SUB on which the second encapsulation layer PCL is formed so as to cover upper surfaces and side surfaces of each of the second encapsulation layer PCL and the first encapsulation layer PAS1. The third encapsulation layer PAS2 may minimize or block penetration of external moisture or oxygen into the first encapsulation layer PAS1 and the organic encapsulation layer PCL. For example, the third encapsulation layer PAS2 is formed of an inorganic insulating material such as silicon nitride (SiNₓ), silicon oxide (SiOₓ), silicon oxynitride (SiON), or aluminum oxide (Al₂O₃).

Referring to FIG. 7, a touch sensor TS may be disposed on the encapsulation layer ENCAP. The structure of the touch sensor will be described in detail below.

A touch buffer layer T-BUF may be disposed on the encapsulation layer ENCAP. The touch sensor TS may be disposed on the touch buffer layer T-BUF.

The touch sensor TS may include touch sensor metals TSM and a bridge metal BRG that are located in different layers.

A touch interlayer insulating film T-ILD may be disposed between the touch sensor metals TSM and the bridge metal BRG.

A protective layer PAC may be disposed to cover the touch sensor TS. The protective layer PAC may be an organic insulating film.

Next, with reference to FIG. 7, a stacked structure of a first optical area OA1 will be described.

Referring to FIG. 7, an emission area EA in the first optical area OA1 may have substantially the same stacked structure as the emission area EA in the general area NA. Accordingly, a stacked structure of a first transmission area TA1 in the first optical area OA1 will be described in detail below. The emission area EA in the first optical area OA1 is exemplarily illustrated in FIG. 7 as regions in the first optical area OA1 excluding the first transmission area TA1.

A cathode electrode CE is disposed in the general area NA and the first optical area OA1, but in the second transmission area TA2 in the second optical area OA2, the cathode electrode CE may not be disposed. That is, the second transmission area TA2 in the second optical area OA2 may correspond to an opening of the cathode electrode CE.

In addition, in the general area NA and the first optical area OA1, a light shield layer LS including at least one of a first metal layer ML1 and a second metal layer ML2 may be disposed in the emission area EA, but in the first transmission area TA1 in the first optical area OA1, the light shield layer LS may not be disposed. That is, the first transmission area TA1 in the first optical area OA1 may correspond to an opening of the light shield layer LS.

The substrate SUB and various insulating films MBUF, ABUF1, ABUF2, GI, ILD1, ILD2, PAS0, PLN (PLN1, PLN2), BANK, ENCAP (PAS1, PCL, PAS2), T-BUF, T-ILD, and PAC, which are disposed in the emission area EA included in the general area NA and the first optical area OA1, may also be disposed in the first transmission area TA1 in the first optical area OA1.

However, in addition to insulating materials disposed in the emission area EA included in the general area NA and the first optical area OA1, material layers having electrical characteristics (for example, metal material layers or semiconductor layers) may not be disposed in the first transmission area TA1 in the first optical area OA1.

For example, referring to FIG. 7, metal material layers ML1, ML2, GME1, GM, TM1, SD1, and SD2 and a semiconductor layer ACT1 related to a transistor may not be disposed in the first transmission area TA1.

In addition, referring to FIG. 7, an anode electrode AE and a cathode electrode CE included in the light-emitting device ED may not be disposed in the second transmission area TA2. However, the emission layer EL may or may not be disposed in the second transmission area TA2.

In addition, referring to FIG. 7, the touch sensor metal TSM and the bridge metal BRG included in the touch sensor TS may also not be disposed in the first transmission area TA1 in the first optical area OA1.

Accordingly, by not disposing material layers having electrical characteristics (for example, metal material layers, semiconductor layers, and the like) in the first transmission area TA1 in the first optical area OA1, the light transmittance of the first transmission area TA1 in the first optical area OA1 may be provided. Accordingly, the first optical electronic device 11 may receive light transmitted through the first transmission area TA1 and perform a corresponding function (for example, image sensing).

Because all or part of the first transmission area TA1 in the first optical area OA1 overlaps the first optical electronic device 11, for the normal operation of the first optical electronic device 11, the transmittance of the first transmission area TA1 in the first optical area OA1 needs to be further increased.

To this end, in the display panel PNL of the display device 100 according to embodiments of the invention, the first transmission area TA1 in the first optical area OA1 may have a transmittance improvement structure (TIS).

Referring to FIG. 7, a plurality of insulating films included in the display panel PNL may include buffer layers MBUF, ABUF1, and ABUF2 between the substrates SUB1 and SUB2 and the transistors DRT and SCT, planarization layers PLN1 and PLN2 between the transistors DRT and the light-emitting devices ED, and encapsulation layers ENCAP on the light-emitting devices ED.

Referring to FIG. 7, the plurality of insulating films included in the display panel PNL may further include the touch buffer layer T-BUF and the touch interlayer insulating film T-ILD on the encapsulation layer ENCAP.

Referring to FIG. 7, as the transmittance improvement structure TIS, the first transmission area TA1 in the first optical area OA1 may have a structure in which the first planarization layer PLN1 and the passivation layer PAS0 are recessed downward.

Referring to FIG. 7, among the plurality of insulating films, the first planarization layer PLN1 may include at least one uneven portion (or recessed portion). The first planarization layer PLN1 may be an organic insulating film.

When the first planarization layer PLN1 is recessed downward, the second planarization layer PLN2 may serve as an actual planarization layer. The second planarization layer PLN2 may also be recessed downward. In this case, the second encapsulation layer PCL may serve as an actual planarization layer.

Referring to FIG. 7, the recessed portion of the first planarization layer PLN1 and the passivation layer PAS0 may penetrate the insulating films ILD2, ILDB, and GI for forming the transistors DRT and the buffer layers ABUF1, ABUF2, and MBUF located thereunder, and may extend down to the upper portion of the second substrate SUB2.

Referring to FIG. 7, the substrate SUB may include at least one concave portion as the transmittance improvement structure TIS. For example, in the first transmission area TA1, an upper surface of the second substrate SUB2 may be recessed downward or perforated.

Referring to FIG. 7, the first encapsulation layer PAS1 and the second encapsulation layer PCL constituting the encapsulation layer ENCAP may also have a recessed form of the transmittance improvement structure TIS. The second encapsulation layer PCL may be an organic insulating film.

Referring to FIG. 7, the protective layer PAC may be disposed to cover the touch sensor TS on the encapsulation layer ENCAP and may protect the touch sensor TS.

Referring to FIG. 7, the protective layer PAC may have at least one uneven portion as the transmittance improvement structure TIS in a portion overlapping the first transmission area TA1. The protective layer PAC may be an organic insulating film.

Referring to FIG. 7, the touch sensor TS may be formed of mesh-type touch sensor metals TSM. When the touch sensor metals TSM are formed in a mesh type, the touch sensor metals TSM may include a plurality of open areas. Each of the plurality of open areas may correspond in position to the emission area EA of the sub-pixel SP.

To increase the transmittance of the first optical area OA1 over that of the general area NA, an area per unit area of the touch sensor metals TSM in the first optical area OA1 may be smaller than an area per unit area of the touch sensor metals TSM in the general area NA.

Referring to FIG. 7, the touch sensor TS may be disposed in the emission area EA in the first optical area OA1, but the touch sensor TS may not be disposed in the first transmission area TA1 in the first optical area OA1.

Next, with reference to FIG. 7, a stacked structure of the second optical area OA2 will be described.

Referring to FIG. 7, the emission area EA in the second optical area OA2 may have the same stacked structure as the emission area EA in the general area NA. Accordingly, hereinafter, a stacked structure of the second transmission area TA2 in the second optical area OA2 will be described in detail. The emission area EA in the second optical area OA2 is exemplarily illustrated in FIG. 7 as regions in the second optical area OA2 excluding the second transmission area TA2.

In the emission area EA included in the general area NA and the first optical area OA1, the cathode electrode CE is disposed, but in the second transmission area TA2 in the second optical area OA2, the cathode electrode CE may not be disposed. That is, the second transmission area TA2 in the second optical area OA2 may correspond to an opening of the cathode electrode CE.

In addition, in the emission area EA included in the general area NA and the second optical area OA2, a light shield layer LS including at least one of the first metal layer ML1 and the second metal layer ML2 is disposed, but in the second transmission area TA2 in the second optical area OA2, the light shield layer LS may not be disposed. That is, the second transmission area TA2 in the second optical area OA2 may correspond to an opening of the light shield layer LS.

When the transmittance of the second optical area OA2 is the same as the transmittance of the first optical area OA1, the stacked structure of the second transmission area TA2 in the second optical area OA2 may be completely the same as the stacked structure of the first transmission area TA1 in the first optical area OA1.

When the transmittance of the second optical area OA2 is different from the transmittance of the first optical area OA1, the stacked structure of the second transmission area TA2 in the second optical area OA2 may be partially different from the stacked structure of the first transmission area TA1 in the first optical area OA1.

For example, as illustrated in FIG. 7, when the transmittance of the second optical area OA2 is less than the transmittance of the first optical area OA1, the second transmission area TA2 in the second optical area OA2 may not have the transmittance improvement structure TIS. As part of this, the first planarization layer PLN1 and the passivation layer PAS0 in the second optical area OA2 may not be recessed. In addition, the width of the second transmission area TA2 in the second optical area OA2 may be less than the width of the first transmission area TA1 in the first optical area OA1.

The substrate SUB and various insulating films MBUF, ABUF1, ABUF2, GI, ILD1, ILD2, PAS0, PLN (PLN1, PLN2), BANK, ENCAP (PAS1, PCL, PAS2), T-BUF, T-ILD, and PAC disposed in the emission area EA included in the general area NA and the second optical area OA2 may also be disposed in the second transmission area TA2 in the second optical area OA2.

However, in the emission area EA included in the general area NA and the second optical area OA2, in addition to insulating materials, material layers having electrical characteristics (for example, metal material layers, semiconductor layers, and the like) may not be disposed in the second transmission area TA2 in the second optical area OA2.

For example, referring to FIG. 7, metal material layers ML1, ML2, GME1, GM, TM1, SD1, and SD2 related to the transistors, and a semiconductor layer ACT1 may not be disposed in the second transmission area TA2 in the second optical area OA2.

In addition, referring to FIG. 7, the anode electrode AE and the cathode electrode CE included in the light-emitting device ED may not be disposed in the second transmission area TA2 in the second optical area OA2. However, the emission layer EL may or may not be disposed in the second transmission area TA2 in the second optical area OA2.

In addition, referring to FIG. 7, the touch sensor metals TSM and the bridge metal BRG included in the touch sensor TS may also not be disposed in the second transmission area TA2 in the second optical area OA2.

Accordingly, by not disposing material layers having electrical characteristics (for example, metal material layers, semiconductor layers, and the like) in the second transmission area TA2 in the second optical area OA2, the light transmittance of the second transmission area TA2 in the second optical area OA2 may be provided. Accordingly, the second optical electronic device 12 may receive light transmitted through the second transmission area TA2 and perform a corresponding function (for example, detecting the approach of an object or a human body, detecting external illuminance, and the like).

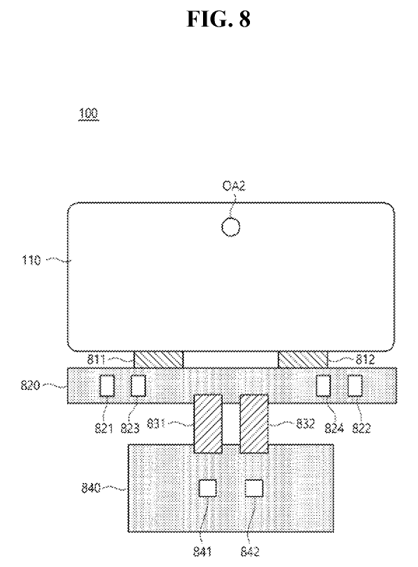

FIG. 8 is a diagram illustrating the display device 100 according to embodiments of the invention.

The display panel 110 may be connected to a first source film 811 and a second source film 812.

The first source film 811 and the second source film 812 may be flexible printed circuit boards. The first source film 811 and the second source film 812 may have components mounted thereon for driving the display panel 110.

A source printed circuit board 820 may be connected to the first source film 811 and the second source film 812.

One side of the source printed circuit board 820 may be connected to the first source film 811 and the second source film 812, and the other side of the source printed circuit board 820 may be connected to a first connection film 831 and a second connection film 832.

The other side of the source printed circuit board 820 may be opposite to the one side of the source printed circuit board 820.

A first gamma circuit 821, a second gamma circuit 822, a first storage circuit 823, and a second storage circuit 824 may be disposed on the source printed circuit board 820.

The first storage circuit 823 and the second storage circuit 824 may store image data in which gamma information is reflected. The first gamma circuit 821 and the second gamma circuit 822 may transmit image data, including the applied gamma information, externally.

The first gamma circuit 821 may receive image data stored in the first storage circuit 823. The second gamma circuit 822 may receive image data stored in the second storage circuit 824.

A control printed circuit board 840 may be connected to the first connection film 831 and the second connection film 832. A first controller 841 and a second controller 842 may be disposed on the control printed circuit board 840.

The first controller 841 may control the first gamma circuit 821 and the first storage circuit 823. The second controller 842 may control the second gamma circuit 822 and the second storage circuit 824.

Hereinafter, signal transmission between the components of the display device 100 will be described.

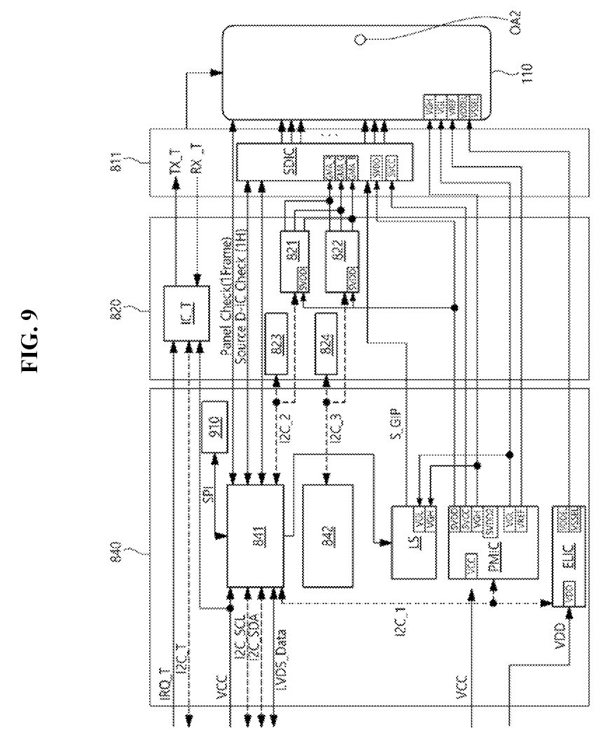

FIG. 9 illustrates a diagram of signal transmission paths in the display device 100 according to embodiments of the invention.

Referring to FIG. 9, the control printed circuit board 840, the source printed circuit board 820, the first source film 811, and the display panel 110 may be identified.

The control printed circuit board 840 may be provided with the first controller 841, the second controller 842, a level shifter LS, a first power circuit PMIC, a second power circuit ELIC, and a memory 910, such as a flash memory.

The source printed circuit board 820 may be provided with a first storage circuit 823, a second storage circuit 824, a first gamma circuit 821, a second gamma circuit 822, and a touch circuit IC_T.

The first source film 811 may be provided with a source drive circuit SDIC.

The above-described components may adopt IRQ, I2C, and LVDS signal transmission methods. The IRQ communication method is a communication method using a hardware interrupt and may be used when an immediate response is required. The LVDS communication method is a high-speed data transmission method using low-voltage differential signals. The I2C communication method is a low-speed serial communication method, has a master-slave structure, and may connect multiple devices with only two signal lines. The IRQ communication method may be defined as an interrupt request communication method, and the I2C communication method may be defined as a serial communication protocol method.

The touch circuit IC_T may receive a first touch signal IRQ_T and a second touch signal I2C_T from a host system. The first touch signal IRQ_T may be a signal transmitted by IRQ communication. The second touch signal I2C_T may be a signal transmitted by I2C communication. The touch circuit IC_T may receive a first base power supply VCC from the host system. The touch circuit IC_T may transmit a touch driving signal TX_T to the display panel 110, and the touch circuit IC_T may receive a touch sensing signal RX_T from the display panel 110.

The first power circuit PMIC may receive the first base power supply VCC from the host system. The first power circuit PMIC may generate a source voltage SVDD, a source base voltage SVCC, a gate high voltage VGH, a gate low voltage VGL, a second source voltage SVDD2, and a reference voltage VREF based on the first base power supply VCC. The first power circuit PMIC may exchange signals with the second power circuit ELIC and the first controller 841 through I2C communication.

The second power circuit ELIC may receive a second base power supply VDD from the host system. The second power circuit ELIC may generate a driving voltage VDDEL and a base voltage VSSEL based on the second base power supply VDD. The second power circuit ELIC may exchange signals with the first power circuit PMIC and the second controller 842 through I2C communication.

The level shifter LS may receive the gate high voltage VGH and the gate low voltage VGL from the first power circuit PMIC. The level shifter LS may be controlled by the first controller 841. The level shifter LS may transmit a GIP signal S_GIP to the outside.

The display panel 110 may receive the gate high voltage VGH, the gate low voltage VGL, and the reference voltage VREF from the first power circuit PMIC. The display panel 110 may receive the driving voltage VDDEL and the base voltage VSSEL from the second power circuit ELIC.

The first controller 841 may receive serial clock I2C_SCL and serial data I2C_SDA through I2C communication. The first controller 841 may receive image data through LVDS communication (LVDS_Data). The first controller 841 may receive the first base power supply VCC from the host system. Referring to FIG. 9, the above-described signals are illustrated as being supplied only to the first controller 841, but the above-described features of the first controller 841 may be equally applied to the second controller 842.

The first controller 841 may receive a first feedback signal (Panel Check) from the display panel 110 at regular intervals. The first controller 841 may check, through the first feedback signal (Panel Check), whether a normal signal has been supplied to the display panel 110. The regular interval may be a period in which a signal is received once during one frame (1 Frame).

The first controller 841 may receive a second feedback signal (Source D-IC Check) from the source drive circuit SDIC at regular intervals. The first controller 841 may check, through the second feedback signal (Source D-IC Check), whether a normal signal has been supplied to the display source drive circuit SDIC. The regular interval may be a period in which a signal is received once during a 1H period.

The first controller 841 may be electrically connected to the first storage circuit 823 and the first gamma circuit 821. The first controller 841 may exchange signals with the first storage circuit 823 and the first gamma circuit 821 through I2C communication.

The second controller 842 may be electrically connected to the second storage circuit 824 and the second gamma circuit 822. The second controller 842 may exchange signals with the second storage circuit 824 and the second gamma circuit 822 through I2C communication.

The first gamma circuit 821 and the second gamma circuit 822 may receive the source voltage SVDD from the first power circuit PMIC. The first gamma circuit 821 and the second gamma circuit 822 may convert image data in a digital state into data voltages in an analog state. At this time, the first gamma circuit 821 and the second gamma circuit 822 may generate analog voltages based on the source voltage SVDD.

The source drive circuit SDIC may receive gamma voltages GMA from the first gamma circuit 821 and the second gamma circuit 822, where the gamma voltages GMA may include GMA_R, GMA_G, and GMA_B gamma voltages for red, green, and blue colors, respectively, for example . The source drive circuit SDIC may receive the source voltage SVDD and the source base voltage SVCC from the first power circuit PMIC.

The source drive circuit SDIC may generate data voltages to be supplied to the display panel 110 based on the gamma voltages GMA supplied from the first gamma circuit 821 and the second gamma circuit 822. Alternatively, the source drive circuit SDIC may transmit the gamma voltages GMA supplied from the first gamma circuit 821 and the second gamma circuit 822 as image data to the display panel 110.

The display panel 110 may include the general area NA and the optical area OA2. Referring to FIG. 9, for convenience of explanation, only the second optical area OA2 is illustrated in the display panel 110.

The arrangement density of sub-pixels disposed in the general area NA may be different from the arrangement density of sub-pixels disposed in the optical area OA2. The above-described arrangement density may refer to PPI. Because the general area NA and the optical area OA2 have different arrangement densities, the degree of compensation for the sub-pixels may differ from each other. That is, a compensation value for image data in the general area NA may be different from a compensation value for image data in the optical area OA2.

Compensation for image data may be performed in a test stage of the display device 100. For example, there may be a test stage for maintaining uniform luminance of the display device 100. In the test stage, after checking the luminance uniformity of the display panel 110, compensation data may be added to the image data so that the luminance becomes uniform.

The process of generating compensation data may be performed for each of the sub-pixels. However, in this case, there may be a problem in that the storage capacity required in the memory becomes excessively large. Accordingly, the process of generating compensation data may be performed in units of predetermined groups of sub-pixels.

When only one gamma circuit is provided, there is a problem that the general area NA and the optical area OA2 cannot be compensated simultaneously. For example, because a gamma circuit should generate an analog voltage based on digital data, the gamma circuit may include physical configurations for distributing voltages based on digital information. The gamma voltages GMA for the general area NA and the gamma voltages GMA for the optical area OA2 may not be generated in the same gamma circuit.

Accordingly, the first gamma circuit 821 may generate general gamma voltages GMA for the general area NA, and the second gamma circuit 822 may generate optical gamma voltages GMA for the optical area OA2.

The first gamma circuit 821 may be controlled by the first controller 841. The first gamma circuit 821 may receive general image data from the first controller 841. The first gamma circuit 821 may receive general image compensation data from the first storage circuit 823. The first gamma circuit 821 may generate the general gamma voltages GMA based on the general image data and the general image compensation data.

Alternatively, the first controller 841 may receive the general image compensation data from the first storage circuit 823 and may subsequently generate general final image data based on the general image compensation data and the general image data. The first gamma circuit 821 may generate the general gamma voltages GMA based on the general final image data.

The source drive circuit SDIC may receive the general gamma voltages GMA from the first gamma circuit 821. The source drive circuit SDIC may generate a general data voltage based on the general gamma voltages GMA. The source drive circuit SDIC may supply the general data voltage to the sub-pixels disposed in the general area NA.

The second gamma circuit 822 may be controlled by the second controller 842. The second gamma circuit 822 may receive optical image data from the second controller 842. The second gamma circuit 822 may receive optical image compensation data from the second storage circuit 824. The second gamma circuit 822 may generate the optical gamma voltages GMA based on the optical image data and the optical image compensation data.

Alternatively, the second controller 842 may receive the optical image compensation data from the second storage circuit 824, and may subsequently generate optical final image data based on the optical image compensation data and the optical image data. The second gamma circuit 822 may generate the optical gamma voltages GMA based on the optical final image data.

The source drive circuit SDIC may receive the optical gamma voltages GMA from the second gamma circuit 822. The source drive circuit SDIC may generate an optical data voltage based on the optical gamma voltages GMA. The source drive circuit SDIC may supply the optical data voltage to the sub-pixels disposed in the optical area OA2.

Embodiments of the invention provide a display device capable of improving luminance uniformity through a plurality of gamma circuits.

Embodiments of the invention also provide a display device capable of improving luminance uniformity of both a general area and an optical area through a plurality of gamma circuits.

Embodiments of the invention further provide a display device capable of achieving low power consumption by uniformly compensating luminance.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel including a general area and an optical area different from the general area;
a source drive circuit configured to supply a voltage for displaying an image to the display panel;
a first gamma circuit configured to supply a general gamma voltage to the source drive circuit;
a second gamma circuit configured to supply an optical gamma voltage different from the general gamma voltage to the source drive circuit;
a first controller configured to control the first gamma circuit and supply general image data to the first gamma circuit; and
a second controller configured to control the second gamma circuit, supply optical image data to the second gamma circuit, and control a target different from a target controlled by the first controller.

2. The display device according to claim 1, wherein:
the source drive circuit generates a general data voltage based on the general gamma voltage; and
the source drive circuit generates an optical data voltage based on the optical gamma voltage.

3. The display device according to claim 2, wherein:
the source drive circuit supplies the general data voltage to a sub-pixel disposed in the general area; and
the source drive circuit supplies the optical data voltage to a sub-pixel disposed in the optical area.

4. The display device according to claim 1, wherein an arrangement density of a sub-pixels disposed in the optical area is lower than an arrangement density of a sub-pixels disposed in the general area.

5. The display device according to claim 1, wherein:
the optical area is an area in which sub-pixels for displaying an image are disposed; and
the optical area overlaps an optical device.

6. The display device according to claim 5, wherein the optical device is a camera sensor or an optical sensor.

7. The display device according to claim 1, further comprising:
a first storage circuit electrically connected to the first gamma circuit and the first controller, the first storage circuit being configured to store general image compensation data; and
a second storage circuit electrically connected to the second gamma circuit and the second controller, the second storage circuit being configured to store optical image compensation data different from the general image compensation data.

8. The display device according to claim 7, wherein:
the first gamma circuit generates the general gamma voltage based on the general image data transmitted from the first controller and the general image compensation data supplied from the first storage circuit; and
the second gamma circuit generates the optical gamma voltage based on the optical image data transmitted from the second controller and the optical image compensation data supplied from the second storage circuit.

9. The display device according to claim 7, wherein:
the first controller receives the general image compensation data from the first storage circuit, the first controller generates general final image data based on the general image data and the general image compensation data, and the first controller supplies the general final image data to the first gamma circuit; and
the second controller receives the optical image compensation data from the second storage circuit, the second controller generates optical final image data based on the optical image data and the optical image compensation data, and the second controller supplies the optical final image data to the second gamma circuit.

10. The display device according to claim 7, wherein:
the first gamma circuit transmits signals to the first controller and the first storage circuit by a serial communication protocol; and
the second gamma circuit transmits signals to the second controller and the second storage circuit by the serial communication protocol.

11. The display device according to claim 1, wherein the number of targets controlled by the first controller is greater than the number of targets controlled by the second controller.

12. The display device according to claim 1, wherein the first controller receives a first feedback signal from the display panel, and the first controller receives a second feedback signal from the source drive circuit.

13. The display device according to claim 12, wherein a period in which the second feedback signal is supplied to the first controller is shorter than a period in which the first feedback signal is supplied to the first controller.

14. The display device according to claim 1, further comprising:
a first power circuit configured to generate a source voltage, a gate high voltage, and a gate low voltage;
a second power circuit configured to generate a driving voltage and a base voltage; and
a level shifter configured to receive the gate high voltage and the gate low voltage from the first power circuit.

15. The display device according to claim 14, wherein:
the first power circuit supplies the source voltage to the first gamma circuit and the second gamma circuit;
the first gamma circuit generates the general gamma voltage based on the source voltage; and
the second gamma circuit generates the optical gamma voltage based on the source voltage.

16. The display device according to claim 14, wherein the first controller communicates signals with the first power circuit and the second power circuit by a serial communication protocol.

17. The display device according to claim 14, wherein the first controller is electrically connected to the level shifter and controls the level shifter.

18. The display device according to claim 1, further comprising a flash memory configured to transmit signals to the first controller and to receive signals from the first controller through serial communication protocol.

19. The display device according to claim 1, further comprising a touch circuit configured to supply a touch driving signal to the display panel, wherein:
the touch circuit receives a touch sensing signal from the display panel; and
the touch circuit communicates signals with an external device by a serial communication protocol and an interrupt request communication protocol.

20. The display device according to claim 1, further comprising:
a control printed circuit board on which the first controller and the second controller are disposed; and
a source printed circuit board on which the first gamma circuit and the second gamma circuit are disposed.
